(19) United States
(12) Patent Application Publication
(10) Pub. No.: US 2003/0042594 A1
(43) Pub. Date: Mar. 6, 2003

(54) Semiconductor package and method of manufacturing lead

(76) Inventor: Takashi Hosaka, Chiba (JP)

Correspondence Address: ADAMS & WILKS, 31st Floor, 50 Broadway, New York, NY, 10004, US

(21) Appl. No.: 09/941,128

(22) Filed: Aug. 28, 2001

(51) Int. Cl. H01L 23/48

(52) U.S. Cl. 257/690

(57) ABSTRACT

It is intended to provide a configuration of a semiconductor package used for manufacturing a small high-quality semiconductor package with a flat lead and to provide a method of manufacturing a lead frame. The semiconductor package with a flat lead is formed to have a lead frame with its lead portion made thinner than its foot portion.

### BACKGROUND OF THE INVENTION

1. Field of the Invention

The present invention relates to a method of forming a lead frame of a flat lead package.

2. Description of the Related Art

A lead and a tab of a lead frame of a flat lead package are conventionally formed through bending of the lead frame. That is, in FIG. 3, a lead portion 37 of a lead frame 31 is bent in a suitable shape with a mold or the like.

The precision of the lead portion formed through the bending of the lead frame 31 shown in FIG. 3 is not so high. In other words, when the lead frame has a thickness of 0.2 mm, the precision of the lead portion before the bending is ±0.01 mm but that after the bending is degraded to ±0.05 mm. Such degradation in the precision after the bending is caused by elastic restoration of the lead portion bent and depending on the precision of the mold used for the bending.

Furthermore, when wiring 36 is to be attached, the lead portion 37 is held by a fixture having a shape corresponding to the bent shape of the lead portion 37 in order to fix the lead portion 37 of the bent portion. However, because of poor precision of the lead portion 37, the holding by the fixture does not work well and thus the wiring 36 does not adhere to the lead portion 37 securely. Thus, there arise problems such as decrease in yield and abnormality in quality.

As a result, extra inspection or the like must be carried out and thus the cost of manufacturing a semiconductor package increases. In addition, after the semiconductor package is placed on the market, the wiring 36 may come off from the lead portion 37 and thus the semiconductor package may malfunction, which may bring about a situation that defects at the market are caused.

### SUMMARY Of THE INVENTION

In order to solve the above-mentioned problems, according to the present invention, a lead portion or a tab portion of a lead frame is reduced in thickness when manufacturing the lead frame. Methods for reducing the thickness include, for example, a press method using a press machine and a method of reducing the thickness by etching. With such a method, the lead portion or the tab portion can be formed with high precision. In addition, the lead frame is not bent, so that no elastic force acts. Thus, flutter of the lead portion is hardly caused.

### BRIEF DESCRIPTION OF THE DRAWINGS

In the accompanying drawings:

FIG. 1 shows a configuration of a semiconductor device of the present invention;

FIGS. 2A to 2C show a manufacturing method of a lead frame used in a semiconductor device of the present invention; and

FIG. 3 shows a configuration of a conventional semiconductor device.

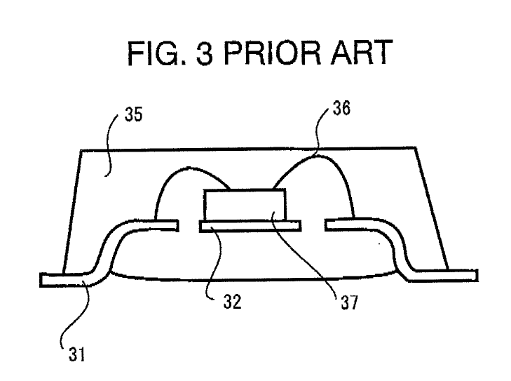

### DETAILED DESCRIPTION OF THE PREFERRED EMBODIMENTS

The present invention relates to a method of manufacturing a lead frame of a flat lead package. An embodiment of the present invention will be described with reference to the figures as follows.

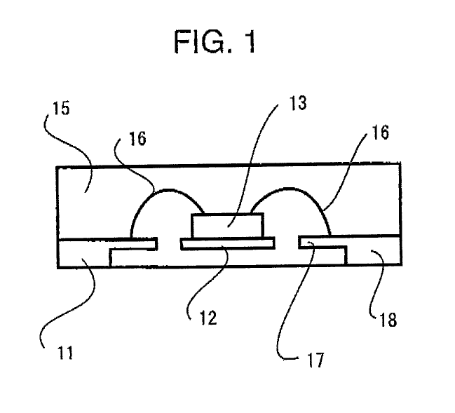

FIG. 1 shows a configuration of a flat lead package with a lead frame of the present invention. A lead frame 11 including a foot portion 18 of a lead is thicker than a lead portion 17. Not only high strength of the lead foot portion 18 is obtained due to the thickness of the foot portion 18 of the lead frame, but also the semiconductor package adheres onto a mounting board with high adhesive strength since a large adhesion area is provided that is used upon mounting the semiconductor package on the mount board. The lead portion 17 can be held reliably during wire bonding, so that wiring 16 adheres to the lead portion 17 securely. Further, a bottom part of the lead portion 17 or a tab portion 12 also is protected with resin and thus improved reliability in moisture resistance or the like also is obtained. In addition, the lead foot portion 18 is cut to have a portion uncovered with the resin 15 of the package and thus is formed as a flat foot. Since an area of the part of the foot portion exposed to the outside of the package is large, it is not necessary to extend the foot portion 18 to the outside of the package to a great extent. As a result, the size of the package can be reduced as compared to conventional packages. Furthermore, the distance required for the transition from a thick portion to a thin portion of the lead frame can be made considerably short. Hence, the size of the semiconductor package can be reduced as compared to that in the conventional case where the distance required for formation of the bent portion has to be provided.

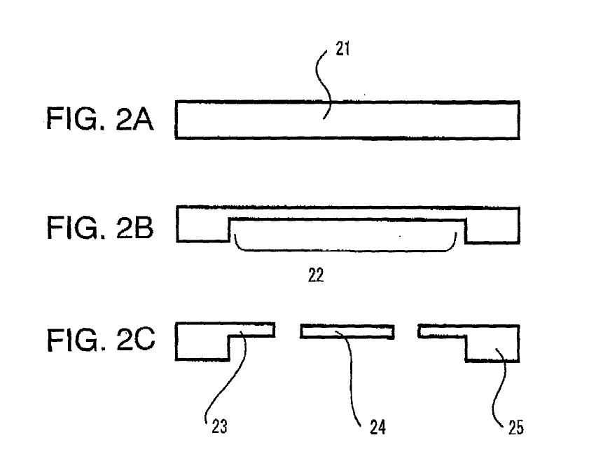

Next, the description is directed to a method of manufacturing a lead frame of the present invention. FIG. 2A shows a flat lead frame 21. This lead frame 21 can be made thicker than a conventional lead frame. The degree to which the thickness of the lead frame 21 can be increased depends on how thick the resin is provided under the lead portion shown in FIG. 1. For instance, when the resin provided under the lead portion is required to have a thickness of 0.2 mm, the original thickness of the lead frame 21 should be 0.3 mm since the lead portion 27 of the lead frame has a thickness of about 0.1 mm. when the resin under the lead portion has a thickness of 0.1 mm, the semiconductor package is provided with sufficiently high strength and reliability. Materials of the lead frame 21 include, for example, Cu, a Cu alloy, and a ferrous alloy. Next, as shown in FIG. 2(b), a region of the lead portion and a tab portion of the lead frame 21 is made thinner to form a depressed portion 22. Methods of making the region thinner include, for instance, a press method using a mold, a method of etching a member, and a method of cutting out a member. Any of the aforementioned methods allows the lead frame 21 to be made thinner with high precision. Afterward, as shown in FIG. 2C, the lead portion 23 and the tab portion 24 are formed through the cutting or the etching of the lead frame. The order of the processes shown in FIGS. 2B and 2C may be reversed. In other words, after being cut, the lead frame 21 may be made thinner (may be depressed).

The flat package shown in FIG. 1 can be manufactured using the lead frame produced by the method shown in FIG. 2.

As described above, the method is not employed in which the lead portion and the tab portion of the lead frame are bent, so that excellent adhesion of the wire is achieved. This results in yield increase and quality improvement. In addition, the foot portion 18 of the lead frame is allowed to be thick and thus a semiconductor package with excellent mountability is obtained. Furthermore, since a thick lead frame is used, a strong semiconductor package is obtained and thus a package with excellent quality and high reliability is obtained. Moreover, it is not necessary to provide a length of bent portion of the lead portion, so that the lead frame can be made small, i.e. the size of the semiconductor package can be reduced.

The present invention may be embodied in other forms without departing from the spirit or essential characteristics thereof. The embodiments disclosed in this application are to be considered in all respects as illustrative and not limiting. The scope of the invention is indicated by the appended claims rather than by the foregoing description, and all changes which come within the meaning and range of equivalency of the claims are intended to be embraced therein.

What is claimed is:

1. A semiconductor package comprising:
a lead frame having a foot portion thicker than a lead portion thereof and a foot portion, a semiconductor on the foot portion, a wire connected to the semiconductor and the lead frame, and resin on the lead frame.

2. A method of manufacturing a lead frame used in a semiconductor device, comprising the steps of etching the lead frame, and mounting a semiconductor on the lead frame.

3. A method of manufacturing a lead frame as claimed in claim 2, wherein a lead portion is thinner by etching.

4. A method of manufacturing a lead frame as claimed in claim 2, wherein a TAB portion is thinner by etching.

5. A method of manufacturing a lead frame used in a semiconductor device, comprising the steps of:
etching the lead frame, and mounting a semiconductor on the lead frame wherein a lead portion or a tab portion of a lead frame is made thinner by a press method.

6. A method of manufacturing a lead frame used in a semiconductor device comprising the steps of: etching the lead frame, and mounting a semiconductor on the lead frame, wherein a lead portion or a tab portion of a lead frame is made thinner by a cutout method.
